(19) United States
(12) Patent Application Publication
(10) Pub. No.: US 2012/0319083 A1
(43) Pub. Date: Dec. 20, 2012

(54) NANOROD SEMICONDUCTOR DEVICE HAVING A CONTACT STRUCTURE, AND METHOD FOR MANUFACTURING SAME

(75) Inventors: Sang Wuk Lee, Seoul (KR); Tae Won Kang, Seoul (KR); Gennady Panin, Seoul (KR); Hak Dong Cho, Gyeonggi-do (KR)

(73) Assignee: Dongguk University Industry-Academic Cooperation F, Seoul (KR)

(21) Appl. No.: 13/518,238

(22) PCT Filed: Dec. 21, 2010
(86) PCT No.: PCT/KR2010/009158

§ 371 Date: Aug. 30, 2012

(30) Foreign Application Priority Data
Dec. 22, 2009 (KR) 10-2009-0129029

(51) Int. Cl. H01L 29/38; H01L 21/205; H01L 21/208; H01L 21/203

(52) U.S. Cl. 257/29; 438/455; 257/E21.091; 257/E21.101; 257/E21.114; 257/E29.105

(57) ABSTRACT

Disclosed is a nanorod semiconductor device having a contact structure, and a method for manufacturing the same. The nanorod semiconductor device having a contact structure according to one embodiment of the present disclosure includes: a transparent wafer; a transparent electrode layer formed on the transparent wafer; a nanorod layer including a plurality of semiconductor nanorods doped with dopants having a first polarity and grown on the transparent electrode layer; and a single crystal semiconductor layer doped with dopants having a second polarity and forming a certain physical contact with the ends of the semiconductor nanorods.

### TECHNICAL FIELD

The present disclosure relates to a nanorod semiconductor device. More particularly, the present disclosure relates to a nanorod semiconductor device having a contact structure and a method for fabricating the same.

### BACKGROUND ART

Active studies have been conducted to develop novel optical devices using the nanostructure of a material. In the structures having a size of several tens of nanometers, including quantum dots, nanopowder, nanowires, nanotubes, quantum wells and nanocomposites, some optical, electrical, magnetic and dielectric properties different significantly from those of the existing thin film and bulk structures are realized due to a so-called electron confinement phenomenon. Thus, many studies have been conducted to develop devices capable of increasing operation efficiency under lower electric power. This conforms to the current trend of energy saving and environmental conservation.

Among different nanostructures, one-dimensional structures having a large aspect ratio are called nanowires or nanorods, and synthesis thereof using various materials has been developed significantly. Particular examples of such nanostructures include carbon nanotubes (CNT), cobalt silicide (CoSi), etc. Particularly, it is known that nanostructures grown in the form of nanorods have the advantages of higher crystallinity and lower potential density as compared to those grown in the form of thin films. Carbon nanotube powder has already been developed commercially as a transparent electrode or a negative electrode part for electric field emission.

However, such nanorods are not sufficient to be used in any functional device other than a transparent electrode, because they have an excessively small size and low strength. There has been an attempt to develop a field emission transistor (FET) or the like by forming a junction between an individual semiconductor nanorod and a metal, followed by heat treatment. In addition, there has been developed a process including growing semiconductor nanorods on a heterogeneous wafer, filling a gap between semiconductor nanorods with an amorphous matrix material, such as silicon dioxide or polyimide, and planarizing the top thereof to form a junction with a metal. However, such a process is still problematic in that the resultant nanorods have low length uniformity and are limited in light emitting surfaces. It is required for a device containing nanorods to be linked amicably with a follow-up process, such as forming an electrode.

Among various materials applied to optoelectric devices, zinc oxide (ZnO) nanorods are prominent as a material capable of providing UV or blue-range optical devices. However, they have p-doping difficulties because of a self-compensation effect and excessively high crystallinity. Diodes obtained by heterogeneous growth of an n-type zinc oxide nanorod layer on a p-type wafer of another semiconductor material allows no light emission, and thus is used for optical receivers. Even if such diodes allow light emission, light emission is limited to a green light or IR region and they are not amenable to UV emission. It is thought that this results from formation of a large amount of defects at the growth interface upon heterogeneous junction.

Therefore, in order to obtain a functional device using semiconductor nanorods having high chemical stability, excellent electrical properties and high crystallinity, it is required to solve p-doping difficulties of zinc oxide, to remove defects at the growth interface upon heterogeneous junction when p-doping of nanorods is difficult, and to facilitate follow-up processes after the growth of nanorods.

### DISCLOSURE

### Technical Problem

A technical problem to be solved by the present disclosure is to provide a semiconductor device having a contact structure, which overcomes interfacial defects, such as dislocation, occurring upon heterogeneous growth of semiconductor nanorods to facilitate UV emission of a device and facilitates a follow-up process.

Another technical problem to be solved by the present disclosure is to provide a method for fabricating a semiconductor device having a contact structure, by which a device solving p-doping difficulties in developing a functional device using semiconductor nanorods, overcoming interfacial defects occurring upon heterogeneous growth of semiconductor nanorods, and facilitating a follow-up process is obtained.

### Technical Solution

In one general aspect, there is provided a semiconductor device having a contact structure, including: a transparent wafer; a transparent electrode layer formed on the transparent wafer; a nanorod layer including a plurality of semiconductor nanorods doped with dopants having a first polarity and grown on the transparent electrode layer; and a single crystal semiconductor layer doped with dopants having a second polarity and forming a certain physical contact with the ends of the semiconductor nanorods.

In another general aspect, there is provided a method for fabricating a semiconductor device having a contact structure, including: forming a transparent electrode layer on a transparent wafer; growing a plurality of semiconductor nanorods doped with dopants having a first polarity on the transparent electrode layer to form a nanorod layer; allowing the nanorod layer to be in contact with a single crystal semiconductor layer doped with dopants having a second polarity; and applying a predetermined level of pressure to the top surface of the single crystal semiconductor layer to fix the single crystal semiconductor layer to the nanorod layer.

### Advantageous Effects

According to the embodiments of the present disclosure, it is possible to overcome p-type semiconductor doping difficulties, while maintaining the advantages of nanostructures. It is also possible to provide a device capable of UV emission by a simple a process.

### DESCRIPTION OF DRAWINGS

FIG. 1 is a schematic view showing the layered structure of a semiconductor device having a contact structure according to an embodiment of the present disclosure;

FIGS. 2 to 4b are schematic views illustrating a process for fabricating the semiconductor device as shown in FIG. 1;

FIG. 5 is a schematic view showing another embodiment of the semiconductor device of FIG. 1 further including a metal layer;

FIG. 6 is a schematic view showing still another embodiment of the semiconductor device of FIG. 1 further including a heat sink layer;

FIG. 7 is an I-V (current-voltage) graph of the light emitting device obtained according to the structure of FIG. 1; and

FIG. 8 shows a light emission spectrum of the light emitting device according to the structure of FIG. 1 in a UV range.

### DETAILED DESCRIPTION OF MAIN ELEMENTS

10: transparent wafer 20: transparent electrode layer

30: semiconductor nanorod layer doped with dopants having first polarity

40: single crystal semiconductor layer doped with dopants having second polarity

60: metal layer

50: interface between semiconductor nanorod layer and single crystal semiconductor layer

### BEST MODE

Exemplary embodiments now will be described more fully hereinafter with reference to the accompanying drawings, in which exemplary embodiments are shown. This disclosure may, however, be embodied in many different forms and should not be construed as limited to the exemplary embodiments set forth therein.

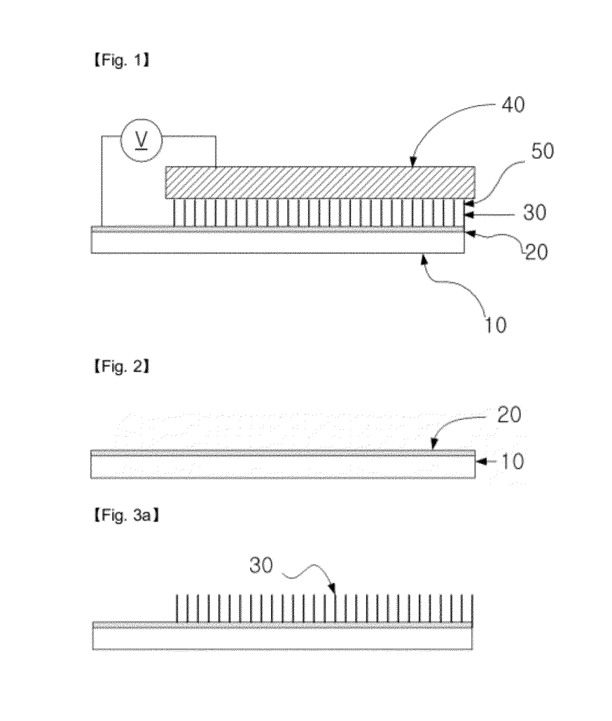

FIG. 1 is a schematic view showing the layered structure of a semiconductor device having a contact structure according to an embodiment of the present disclosure.

The semiconductor device having a contact structure according to an embodiment of the present disclosure includes a transparent electrode layer 20 formed on a transparent wafer 10, a nanorod layer doped with dopants having a first polarity and grown on the transparent electrode layer 20, and a single crystal semiconductor layer 40 doped with dopants having a second polarity and formed on the nanorod layer 30 while being in contact therewith. A power source is applied to the transparent wafer 10 and the single crystal semiconductor layer 40.

The transparent wafer 10 is a base on which semiconductor nanorods doped with dopants having a first polarity are to be grown and serves as a window for light emitted from the device or absorbed into the device. For example, the transparent wafer 10 may include any transparent material selected from glass, sapphire and transparent plastics.

The transparent electrode layer 20 is one brought into contact with the semiconductor nanorod layer doped with dopants having a first polarity and serving as a window through which light is absorbed or emitted

According to some embodiments of the present disclosure, the base on which nanorods are grown is not a semiconductor wafer but the transparent electrode layer 20. The nanorods doped with dopants having a first polarity and grown on the transparent electrode layer 20 may be formed vertically to the transparent wafer 10 or may be formed at a predetermined angle to the transparent wafer 10. The semiconductor nanorods have a length ranging from 0.3 μm to 300 μm and a width ranging from 10 nm to 1,000 nm. The nanorod layer 30 may be formed of monoatomic single crystal semiconductors or polyatomic single crystal compound semiconductors.

The single crystal semiconductor layer 40 doped with dopants having a second polarity is a structure substituting for p-n junction. In general, a semiconductor device includes junction of p-type semiconductors with n-type semiconductors. Such p-n junction may be formed by a diffusion process based on melting of semiconductor materials or ion implantation of dopants, or a simultaneous growth process including injecting dopants when forming a semiconductor thin film or bulk layer. However, in the interface 50 of FIG. 1, the single crystal semiconductor layer 40 is merely in contact with the top of the nanorod layer 30. Thus, any constitutional element of the two layers does not undergo melting and junction caused by heat treatment or other treatments, or the constitutional elements of the two layers are not diffused into each other.

In FIG. 1, when the material doped with dopants having a first polarity is n-typed, the material doped with dopants having a second polarity is p-typed. On the contrary, when the material doped with dopants having a first polarity is p-typed, the material doped with dopants having a second polarity is n-typed. In the case of an n-type semiconductor, it may have a dopant concentration of 1×10¹⁶ to 9×10²⁰/cm³. In the case of a p-type semiconductor, it may have a dopant concentration of 1×10¹⁷ to 9×10²⁰/cm³.

When the nanorod layer 30 includes n-doped semiconductor nanorods and is not capable of p-doping, use of a p-doped heterogeneous single crystal semiconductor layer in the single crystal semiconductor layer 40 solves the problem of p-doping difficulties. This results from the fact that semiconductor nanorods have high crystallinity and an ideal p-n interface is formed when the ends of nanorods having particularly high crystallinity are in contact with a highly crystalline heterogeneous single crystal semiconductor layer.

The method for fabricating a semiconductor device having a contact structure according to an embodiment includes: forming a transparent electrode layer on a transparent wafer; growing a plurality of semiconductor nanorods doped with dopants having a first polarity on the transparent electrode layer to form a nanorod layer; allowing the nanorod layer to be in contact with a single crystal semiconductor layer doped with dopants having a second polarity; and applying a predetermined level of pressure to the top surface of the single crystal semiconductor layer to fix the single crystal semiconductor layer to the nanorod layer. According to an embodiment, a buffer layer (not shown) may be formed additionally for the purpose of growth of nanorods, right before growing the nanorod layer 30. Otherwise, the nanorod layer 30 may be grown directly on the transparent electrode layer 20. Hereinafter, the process of fabricating the semiconductor device having a contact structure according to an embodiment will be explained in more detail with reference to FIG. 2 to FIG. 4b.

FIG. 2 shows the transparent wafer 10 and the transparent electrode layer 20.

The transparent wafer 10 may have a melting point higher than the temperature where the semiconductor nanorod layer is grown. For example, soda lime or Corning-7059 may be used as the transparent wafer 10.

The transparent electrode layer 20 formed on the transparent wafer 10 may include Indium Tin Oxide (ITO), ZnO:Zn, ZnO:Ga, graphene, or the like. For example, a transparent electrode coated with ITO to a thickness of 800 Å and having a conductivity of 200 Ω/□ may be used.

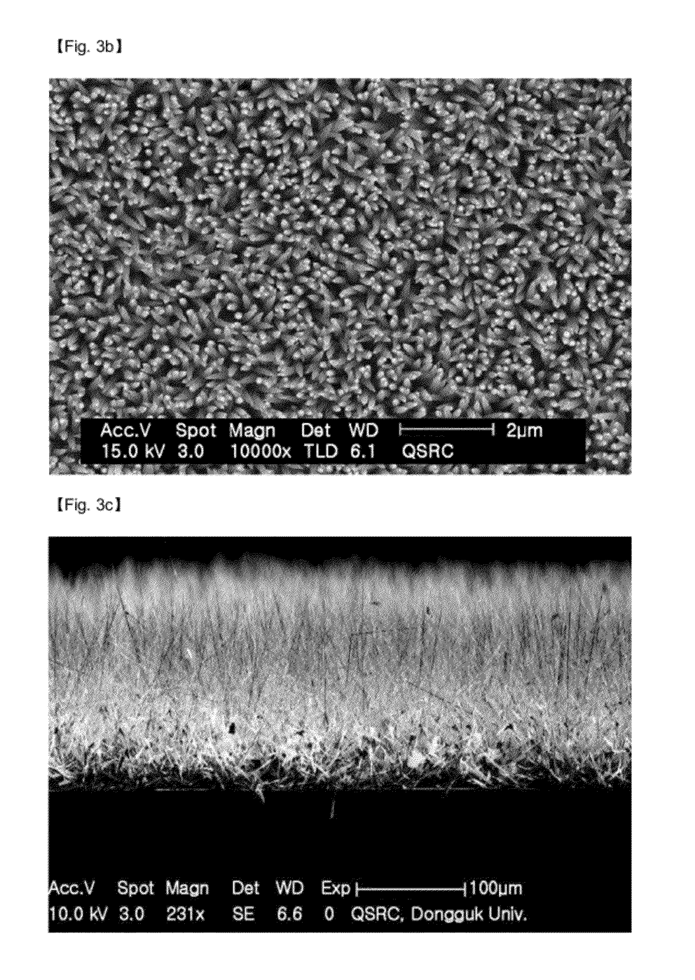

FIG. 3a shows a nanorod layer 30 grown on the transparent electrode layer 20 of FIG. 2 and doped with dopants having a first polarity.

According to some embodiments of the present disclosure, the base on which nanorods are grown is not a semiconductor wafer but the transparent electrode layer 20. The semiconductor nanorods of the nanorod layer 30 may be aligned vertically (90°) to the transparent wafer 10 or the transparent electrode layer 20. However, the semiconductor nanorods may be aligned in an optional direction to the transparent wafer 10. When the nanorod layer 30 cannot be grown directly on the transparent electrode layer 20, it is possible to use a metal-based catalyst process, or a process including forming a homogeneous or heterogeneous buffer layer (not shown) and then forming a nanorod layer of a first polarity. The nanorod layer 30 may be grown by any one of a vapor phase transport process (a process including transporting reactant atoms to a wafer so that they are combined with vapor), a metal-organic source chemical vapor deposition process (a process including combining an organometallic compound with reactant gas and growing the resultant product on a wafer), a sputtering process, a chemical electrolysis deposition process and a hydrothermal growth process, depending on the particular type of a semiconductor material. It is required for the semiconductor nanorods of the nanorod layer 30 to have a length larger than the diffusion distance of a charge carrier. Thus, the semiconductor nanorods have a length of 0.3 μm or more. Preferably, the semiconductor nanorods have a length smaller than 300 μm so that they may be grown with a uniform length. Since the semiconductor nanorods of the nanorod layer 30 tend to show a decrease in crystallinity as their diameter increases, they preferably have a diameter of 10 nm or more. The nanorods of the nanorod layer 30 may have a diameter up to 1,000 nm so that they maintain crystallinity. A range of materials to be used in semiconductor nanorods refers to a range of a gap generated by edges of a valence band and a conduction band forming a forbidden energy band, which may be described by the band theory of the crystal structure of a material. Different semiconductor materials have different energy gaps. In the case of a detector device, a material excited by an excitation light source with a wavelength of 100 nm may have a band gap of 10 eV. Thus, in this case, a range of semiconductors refers to materials having an energy band gap of 0.5-10 eV. Particular examples of materials used in semiconductor nanorods may include ZnO, ZnS, GaN, AlGaN, InGaN, or the like.

FIG. 3b shows zinc oxide nanorods grown by the above-described method as viewed from the top. The nanorod layer 30 of FIG. 3b includes n-doped zinc oxide nanorods grown by a VPT process. The growth temperature is 400-600° C. The nanorods have a length of about 0.5 μm and a diameter of 40 nm, and are aligned substantially vertically to the wafer.

FIG. 3c shows zinc oxide nanorods having a length of 200 μm or more. According to some embodiments of the present disclosure, it is also possible to use zinc oxide nanorods having a length (height) of 200-300 μm.

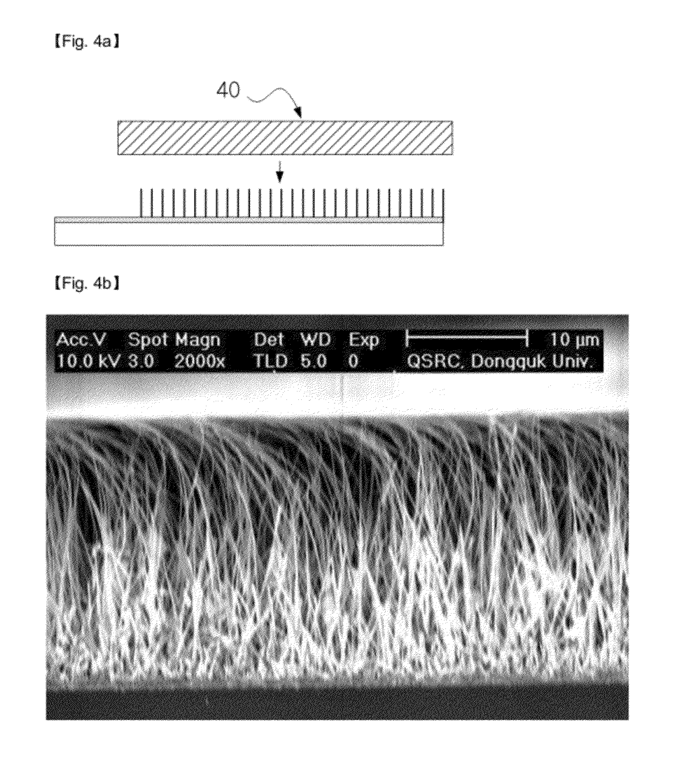

FIG. 4a shows a single crystal semiconductor layer 40 doped with dopants having a second polarity and stacked on the nanorod layer 30.

The single crystal semiconductor layer 40 is fixed to the transparent wafer 10 or the like, while applying an adequate level of pressure ranging from 0.05 to 8 N/cm² to the single crystal semiconductor layer 40. The pressure required for fixing the single crystal semiconductor layer 40 to the nanorod layer 30 may be determined by the shape of nanorods. According to experiments, when applying a pressure higher than 8 N/cm², the rectification property of a device disappeared regardless of the shape of a nanorod layer 30. When using single crystal silicon for the single crystal semiconductor layer 40, it is preferred to remove a silicon dioxide (SiO₂) film on the surface of a wafer.

FIG. 4b shows an embodiment in which the single crystal semiconductor layer 40 is stacked by the process as shown in FIG. 4a and the ends of the semiconductor nanorods are bent. Such bent ends of the semiconductor nanorods maintain a constant contact with the single crystal semiconductor layer 40. Fixing the single crystal semiconductor layer 40 may be carried out with epoxy. More particularly, epoxy may be introduced through the nanorod layer in such a manner that the lateral surface of the single crystal semiconductor layer, the later surface of the transparent electrode layer and the lateral surface of the transparent wafer are partially or totally attached to each other. It is preferred to use epoxy capable of enduring 300° C. to provide against the subsequent metal treatment process.

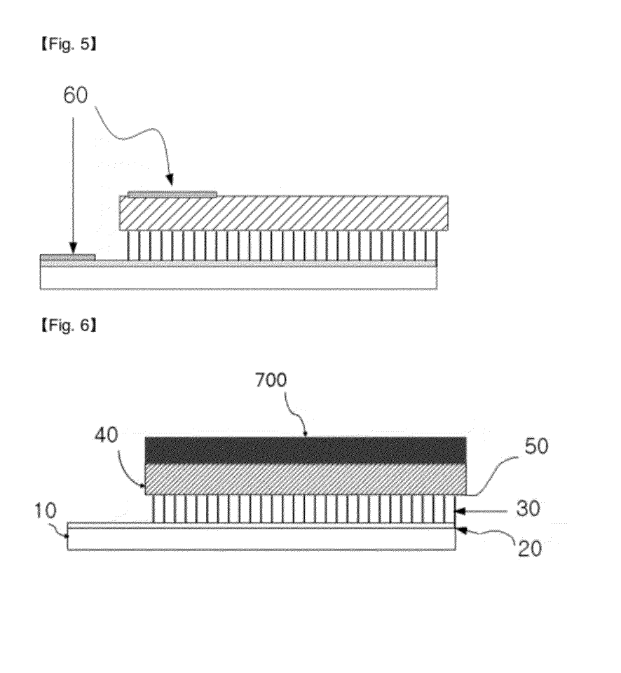

FIG. 5 shows still another embodiment in which a metal layer is formed on the semiconductor device of FIG. 1.

A metal ohmic junction layer 60 is formed at a certain point of each of the transparent electrode layer 20 and the single crystal semiconductor layer 40. For this, a metal layer (e.g. indium) is formed at a certain point of each of the transparent electrode layer 20 and the single crystal semiconductor layer 40, and then heat treatment may be carried out at 200° C. for 10 seconds.

FIG. 6 shows an embodiment in which a heat sink layer is formed on the semiconductor device of FIG. 1.

When operating the semiconductor device according to an embodiment of the present disclosure at 10V or higher, a large amount of heat may be generated. This results from the contact structure of the device and the presence of silicon oxide on the single crystal semiconductor wafer. A heat sink layer 700 attached to the top surface of the single crystal semiconductor layer 40 may help cooling the heat.

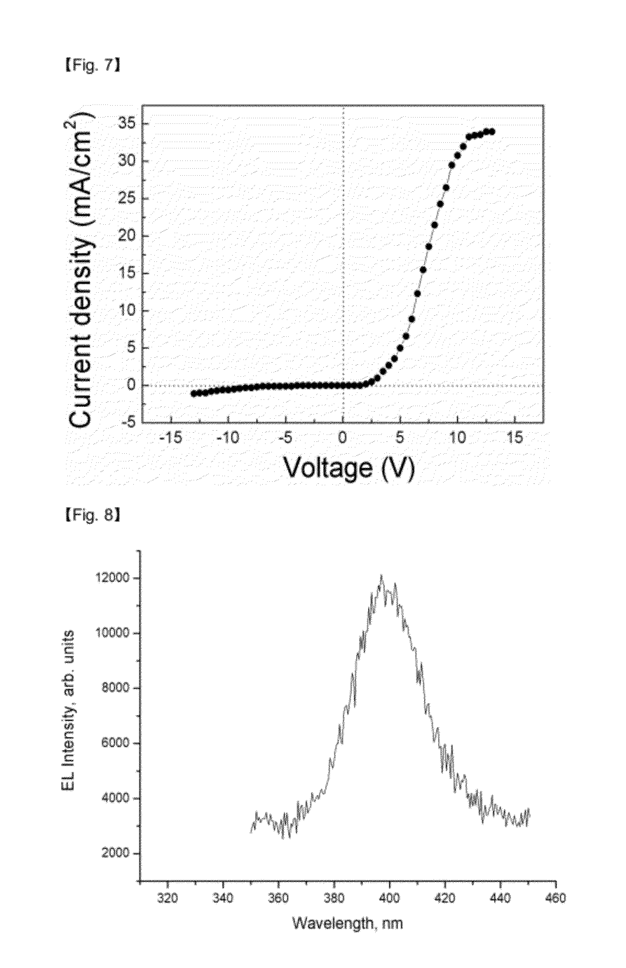

FIG. 7 is an I-V (current-voltage) graph of the light emitting device obtained according to the structure of FIG. 1.

In FIG. 7, single crystal p-type silicon is used for the single crystal semiconductor layer 40. The resistivity is 0.05 Ω/cm. In order to determine the characteristics of the device in FIG. 7, 1 cm×1 cm of an n-doped semiconductor nanorod layer and a p-type silicon wafer are pressed against each other. In FIG. 7, when the voltage is 10V, the forward current is 30 mA/cm² and the reverse current is 0.6 mA/cm², and thus the device shows characteristics as a rectifier.

FIG. 8 shows a light emission spectrum of the light emitting device according to the structure of FIG. 1 in a UV range.

It is to be noted that light is emitted at a wavelength of 400 nm adjacent to a UV region at room temperature. This is because the n-type zinc oxide nanorod layer 30 has very high crystallinity and the p-n contact interface is well defined, while holes are introduced to the n-type zinc oxide nanorod layer. Under those circumstances, it is possible to use a broad band gap and free excitons of zinc oxide nanorods.

Since the above-described semiconductor device is not fabricated by a junction process but by a contact process, it may be referred to as a contact light emitting diode (LED).

While the exemplary embodiments have been shown and described, it will be understood by those skilled in the art that various changes in form and details may be made thereto without departing from the scope of this disclosure as defined by the appended claims. Therefore, it is intended that the scope of the present disclosure includes all embodiments falling within the spirit and scope of the appended claims.

### INDUSTRIAL APPLICABILITY

Various embodiments of the present disclosure may be applied to a light emitting device generating light in a UV region at room temperature and an optical receiver operating in a UV region. Particularly, the embodiments of the present disclosure facilitate fabrication of large-area devices absorbing UV, and may be applied to UV detectors or photovoltaic devices, such as solar cells. In addition, the embodiments of the present disclosure facilitate fabrication of large-area devices emitting UV rays, so that they may be applied to fabrication of lighting devices such as UV-region excitation sources for phosphors. Further, the embodiments of the present disclosure may be applied to touch panels, excitation sources for optical catalyst for hydrogen generation (e.g. hydrogen sources for an engine of hydrogen fuel car), etc.

1. A semiconductor device having a contact structure, comprising:
a transparent wafer;
a transparent electrode layer formed on the transparent wafer;
a nanorod layer comprising a plurality of semiconductor nanorods doped with dopants having a first polarity and grown on the transparent electrode layer; and
a single crystal semiconductor layer doped with dopants having a second polarity and forming a certain physical contact with the ends of the semiconductor nanorods.

2. The semiconductor device having a contact structure according to claim 1, wherein the single crystal semiconductor layer is p-doped when the semiconductor nanorods are n-doped.

3. The semiconductor device having a contact structure according to claim 1, wherein the single crystal semiconductor layer is n-doped when the semiconductor nanorods are p-doped.

4. The semiconductor device having a contact structure according to claim 1, wherein the semiconductor nanorods are aligned vertically to the transparent wafer.

5. The semiconductor device having a contact structure according to claim 1, wherein the semiconductor nanorods are grown at any angle other than a right angle to the transparent wafer.

6. The semiconductor device having a contact structure according to claim 1, wherein the nanorod layer includes any one of a monoatomic single crystal semiconductor and a polyatomic single crystal compound semiconductor.

7. The semiconductor device having a contact structure according to claim 1, wherein the semiconductor nanorods have a length ranging from 0.3 μm to 300 μm and a diameter ranging from 10 nm to 1,000 nm.

8. The semiconductor device having a contact structure according to claim 1, wherein the nanorod layer has a gap generated by edges of a valence band and a conduction band forming a forbidden energy band of 0.5-10 eV.

9. The semiconductor device having a contact structure according to claim 1, wherein the single crystal semiconductor layer is a single crystal silicon wafer.

10. The semiconductor device having a contact structure according to claim 1, which further comprises a metal heat sink layer attached to a top surface of the single crystal semiconductor layer.

11. A method for fabricating a semiconductor device having a contact structure, comprising:
forming a transparent electrode layer on a transparent wafer;
growing a plurality of semiconductor nanorods doped with dopants having a first polarity on the transparent electrode layer to form a nanorod layer;
allowing the nanorod layer to be in contact with a single crystal semiconductor layer doped with dopants having a second polarity; and
applying a predetermined level of pressure to a top surface of the single crystal semiconductor layer to fix the single crystal semiconductor layer to the nanorod layer.

12. The method for fabricating a semiconductor device having a contact structure according to claim 11, which further comprises:
forming metal layers on a region of the top surface of the transparent electrode layer, exposed to the exterior, and on the top surface of the single crystal semiconductor layer; and
subjecting the metal layers to heat treatment to form ohmic junction.

13. The method for fabricating a semiconductor device having a contact structure according to claim 11, wherein the nanorod layer includes any one of a monoatomic single crystal semiconductor and a polyatomic single crystal compound semiconductor.

14. The method for fabricating a semiconductor device having a contact structure according to claim 11, wherein the nanorod layer is formed by growing the semiconductor nanorods directly on the transparent electrode layer.

15. The method for fabricating a semiconductor device having a contact structure according to claim 11, wherein the nanorod layer is formed by growing the semiconductor nanorods by using a catalyst process.

16. The method for fabricating a semiconductor device having a contact structure according to claim 11, wherein the nanorod layer is formed by growing the semiconductor nanorods after forming a buffer layer.

17. The method for fabricating a semiconductor device having a contact structure according to claim 11, wherein the nanorod layer is formed by growing the semiconductor nanorods through any one of a vapor phase transport process, a metal-organic source chemical vapor deposition process, a sputtering process, a chemical electrolysis deposition process and a hydrothermal growth process.

18. The method for fabricating a semiconductor device having a contact structure according to claim 11, wherein the single crystal semiconductor layer is a single crystal silicon wafer.

19. The method for fabricating a semiconductor device having a contact structure according to claim 11, wherein the single crystal semiconductor layer is fixed to the nanorod layer by applying a pressure of 0.05-8 N/cm² to the top surface of the single crystal semiconductor layer.

20. The method for fabricating a semiconductor device having a contact structure according to claim 11, wherein the single crystal semiconductor layer is fixed to the nanorod layer by a process further including introducing epoxy through the nanorod layer, while applying pressure to the top surface of the single crystal semiconductor layer, so that a lateral surface of the single crystal semiconductor layer, a later surface of the transparent electrode layer and a lateral surface of the transparent wafer are attached partially or totally to each other.
